(19) United States
(12) Patent Application Publication
(10) Pub. No.: US 2004/0125580 A1
(43) Pub. Date: Jul. 1, 2004

(54) Mounting capacitors under ball grid array

(75) Inventors: Chee Yee Chung, San Jose, CA (US); Erik William Peter, Hillsboro, OR (US); Alexander Waizman, Zichron Yaakov (IL)

Correspondence Address: Julie L. Reed, MARGER JOHNSON & McCOLLOM, P.C., 1030 S.W. Morrison Street, Portland, OR, 97205, US

(73) Assignee: Intel Corporation, Santa Clara, CA (US)

(21) Appl. No.: 10/334,750

(22) Filed: Dec. 31, 2002

(51) Int. Cl. H05K 7/02

(52) U.S. Cl. 361/794; 361/760; 361/763

(57) ABSTRACT

An apparatus is disclosed. The apparatus has a printed circuit board and one or several integrated circuit substrates mounted to the printed circuit board. At least one SMT component with two or more terminals is arranged between the printed circuit board and the package. In one embodiment, the SMT component replaces interconnects in the ball grid array used to mount the substrate to the printed circuit board while simultaneously connecting the SMT terminals to the substrate and the printed circuit board. The disclosed apparatus of SMT components mount results in significant reduction of inductance of the SMT connection to the substrate.

### BACKGROUND

Surface mount technology involves mounting integrated circuit die and their associated packages directly onto printed circuit boards via an array of interconnects. These interconnects may include solder balls, balls of copper, aluminum, and many other materials, columns, bars, pins, etc. However, for ease of discussion, this array of interconnects will be referred to as ball grid arrays (BGA). Typically, BGAs are used for flip-chip packages, where the chip is mounted to the package upside-down, but may be applicable to wirebond packages as well as other package types.

Current methods for placing capacitors and other surface mount components, such as resistors and inductors, include placing them on the same side of the package as the integrated circuit die, on the printed circuit board next to the package, or on the backside of the circuit board in the shadow, or footprint, of the package on the opposite side of the board.

In any of these configurations, the current from the capacitors has to travel through the parasitic inductance of the printed circuit board due to the vias and planes. Similarly, there is inductance from the ball grid array and the printed circuit board ‘dog-bones.’ The term “dog-bone” in this case refers to the shape created by the etch connection between a BGA pad and it's adjacent via pad. Usually the limitation of a regular BGA technology is that the BGA needs a pad on the printed circuit board (PCB) with which to connect. In order to get into internal layers, a via needs to be placed so as to connect to this BGA pad. Common mother board technologies preclude placing this via inside the BGA pad thus the via is usually placed at about x=+/−25 mil, Y=+/−25 mil offset with respect to the pad of the BGA ball, for 50 mil BGA technology as an example, and the connection between the via pad and the BGA land creates a shape reminiscent of a “dog bone”. An alternative technology that avoids use of “dog bone is “Via-in-pad” technology has been well documented.

The large loop area created by currents running from the integrated circuit die through it's associated package, onto the board to a capacitor and back again to the die leads to a significant path inductance. The on-board capacitors are then limited in their ability to respond to high frequency transient current consumption of the integrated circuits on the die.

Typically, where higher frequency current response is needed, on-package, die side capacitors may be used due to their reduced loop inductance.

However, placing the die side capacitors on the package may cause problems for thermal management and for package routing. A common thermal management technique is to mount a heat sink on top of the integrated circuit die leaving very little height space in between the package surface and the heat sink. Having a capacitor or any other surface mount technology (SMT) component on the die side of the package surface requires adjustment in the placement and possible shape of potential heat sinks and those die-side SMT components, increasing costs and risk of short circuit between the heat sink and capacitor's terminals. These die-side package components may also increase the complexity of package routing and in some cases drive the package to an increase in the number of package routing layers required. This may result in a significant product cost increase.

### BRIEF DESCRIPTION OF THE DRAWINGS

Embodiments of the invention may be best understood by reading the disclosure with reference to the drawings, wherein:

FIG. 1 shows prior art embodiments of mounting capacitors.

FIG. 2 shows a side view of current flow loop for a prior art embodiment for mounting capacitors.

FIG. 3 shows a side view of an embodiment for mounting capacitors

FIG. 4 shows a side view of an embodiment for mounting capacitors in conjunction with a heat sink.

FIG. 5 shows a side view of current flow loop for an embodiment for mounting capacitors.

FIG. 6 shows a ball side view of an embodiment for mounting capacitors.

FIGS. 7a and 7b show a prior art embodiment and an embodiment of a reference plane diagram for input/output signals, respectively.

### DETAILED DESCRIPTION OF THE EMBODIMENTS

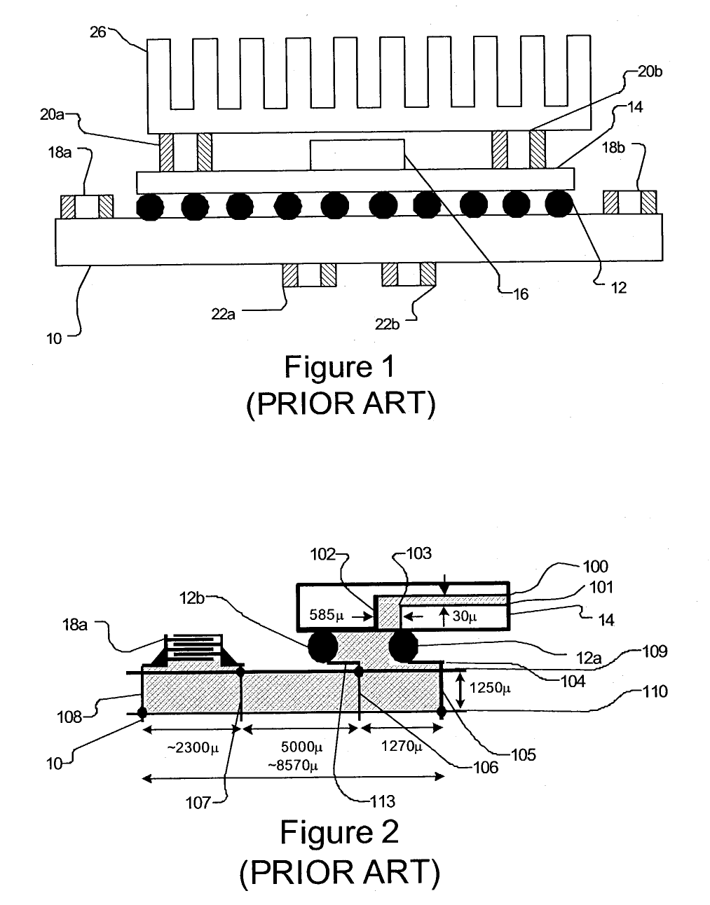

FIG. 1 shows several alternatives of prior art capacitor mountings on an integrated circuit, BGA package and printed circuit board combination. The integrated circuit die 16 may be typically encapsulated inside or on a substrate 14, the combination of which will be referred to as the integrated circuit package, although only the bottom portion of the package is relevant to this discussion. Other portions of the package have been removed from the figure to uncover the integrated circuit die and capacitor locations.

Integrated circuit 16 is electrically connected by means of interconnect bumps or wire bonds to substrate 14 which in turn connects with electrically conductive interconnects, such as BGA ball 12. These connections provide electrical connections between the integrated circuit 16 and its substrate 14, and the board, such as printed circuit board 10. The board 10 may be any type of circuitry card or board, such as a PC card, a motherboard, etc. Current approaches may place the capacitors on the printed circuit board on the same side as the integrated circuit and package, shown as positions 18a and 18b. The disadvantage of 18a and 18b placement is that they significantly congest and constrain signals routing on the printed circuit board 10 as well as may have significant mechanical contention with heat sink retention support keep-out areas.

An alternative approach may place the capacitors on the printed circuit board, but on the opposite side from the integrated circuit and package. These are generally placed inside the shadow, or footprint, of the substrate 14. This embodiment is shown by positions 22a and 22b. While placement of 22a and 22b capacitors is technically feasible and may result in electrical benefits as well as area saving the cost associated with dual side assembly of components on a board 10 is frequently prohibitive to use this technique.

Yet another alternative position could be on the substrate 14. Possibilities are shown by positions 20a and 20b. The disadvantage of 20a and 20b placement is that they significantly congest and constrain signals routing on the substrate 14 as well as may have significant mechanical contention with heat sink 26.

FIG. 2 illustrates a typical example of the current flow path for the capacitor 18a as used in prior art case. While the drawing in FIG. 2 is not accurate to scale for clarity of the drawing the dimensions shown on FIG. 2 aid in understanding of the deficiencies of present art solution and the advantages of embodiments of the current invention. As can be seen in FIG. 2, the current flow loop for an on-board capacitor, such as 18a, starts at the substrate 14 power plane 100, continuing through the substrate power via 102 through power BGA ball 12b, through board dog bone connection 113. The loop then follows a board power via 106 that connects the power dog bone 113 to board power plane 109 that in turn connects through the capacitor power via 107 to the positive side terminal of the capacitor 18a.

The loop is completed by connecting the negative side terminal of capacitor 18a to the ground plane 101 in the substrate 14. The return path starts from capacitor 18a negative terminal connecting to the capacitor ground via 108 to board ground plane 110 which in turn connects by board ground via 105, ground dog bone 104, ground BGA ball 12a, substrate ground via 103 and finally ground plane 101 in the substrate 14.

In the particular example of FIG. 2, the distance between the power plane 100 and ground plane 101 connections on the integrated circuit die is 30 micrometers (μ). The distance between the two substrate vias 102 and 103 is 585 micrometers. The BGA balls 12a and 12b separation is 1270μ. Separation between the board vias 105 and 106 is also 1270μ. Due to various manufacturing keep out design rules the capacitor 18a has to be placed up to 5000μ away from the substrate 14 while the separation between the power plane 109 and ground planes 110 in the board is typically 1250μ. Typical separation of capacitor 18a vias 107 and 108 for an example of a capacitor in a 0603 form factor is about 2300μ

This path contains a fairly large loop area. Specifically the loop area contributed by board connection of capacitor 18a is about (2300+5000+1270)×1250=8570×1250 [μ²]. The large area of the loop leads to high loop inductance, reducing the effectiveness of the capacitors in responding to high frequency transients.

Mounting the capacitor on the die side of the substrate as shown at 20a or 20b in FIG. 1 does not have this large of a loop for the current flow. However, having the capacitor on top of the substrate 14 may increase the profile, creates routing congestion of signals on top layer of substrate 14, and may interfere with other aspects of the apparatus, such as thermal solutions like heat sinks, such as the heat sink 26 shown in FIG. 1.

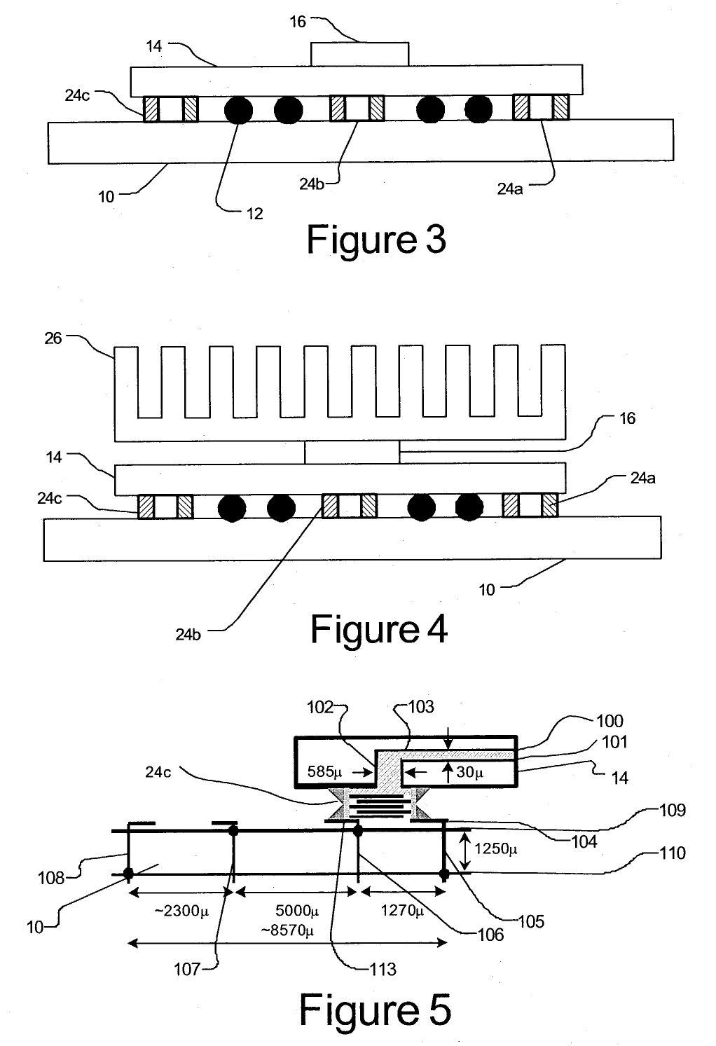

In one embodiment of the invention, the capacitors are mounted between the substrate and the printed circuit board. An example of this embodiment is shown in FIG. 3. All of the prior art connection methods can still be used in addition to the connection type of embodiments of this invention; they are not shown for ease of discussion. The terminals of the capacitors 24a, b and c, may replace the interconnects that could have previously made the connections between the substrate and the printed circuit board. The terminals of the capacitors, shown by the hatched areas of the capacitor 24a, as an example, are connected to the substrate as well as the board, such as a printed circuit board.

In other embodiments, the capacitor may be connected to the substrate only. The connection may be established through solder or other means of electrical and physical connection. In the case that the capacitor terminals are not connected to the board, the closest BGA balls will make the connection through the substrate between the capacitor terminals and the board. However, the method where the capacitor terminals are connected directly to the board and the substrate with the same terminals is electrically more desirable since it will benefit the most from inductance reduction of capacitor connection.

The direct connection to the printed circuit board ensures a quick recharge path for the capacitors from larger bulk capacitors on the board or voltage source as the capacitor terminals may act as direct current paths for the power and ground connections from the substrate to the board. Enabling a direct connection with the printed circuit board may also reduce the number of power and ground ball grid array (BGA) balls or pins needed for proper operation of integrated circuit 16 on the substrate 14.

As can be seen in FIG. 4, mounting the capacitors between the substrate and the printed circuit board does not restrain any possible thermal solutions. In addition, moving the SMT components that would normally be on the board outside the perimeter of the substrate under the footprint of the substrate enables board layout space savings and reduces board routing congestion. This could be a key enabler for smaller form factor board designs in future product generations. Future thermal solutions may require thinning the integrated circuit die. This could decrease the amount of vertical extent from the bottom to the top of the integrated circuit die 16 of FIG. 1, making placement of capacitors 20a and 20b on the substrate as in FIG. 1 impractical. The capacitors may protrude above the top of the die, making packaging more difficult. However, with the placement of the capacitors 24a-c between the substrate 14 of FIG. 4 and the printed circuit board 10, the integrated circuit die 16 could be as thin as needed with no restraints on the physical connection between the heat sink 26 and the die 16.

Further, this placement of capacitors reduces the loop area of the current flow loop. As can be seen in FIG. 5, the distances of the current flow loop from substrate through the capacitor to the power and ground paths on the printed circuit board 10 are of a considerably smaller loop area. The loop previously contained between the BGA balls 12a and 12b, board power plane 109 and ground plane 110 and board vias 105 and 106 of FIG. 2 with the approximate loop area of 8570×1250μ² as well loop area between the dog bones 113 and 104 and BGA balls 12b and 12a of FIG. 2 is eliminated from FIG. 5. This significantly reduces the loop area and therefore the loop inductance of capacitor connection 24c of FIG. 5 to the power and ground planes 100 and 101 of FIG. 2.

This increases the effectiveness of the capacitors when compared against prior art techniques. The 30 micrometers dielectric separation between the die power and ground planes 100 and 101 of the substrate 14 remains the same, as does the 585 micrometers distance between the two substrate 14 vias 102 and 103. However, there is no further area in the current flow loop since the capacitor 24c is placed instead of the former BGA balls 12a and 12b of FIG. 2. This results in a significant reduction in the loop area when compared to the current placement options.

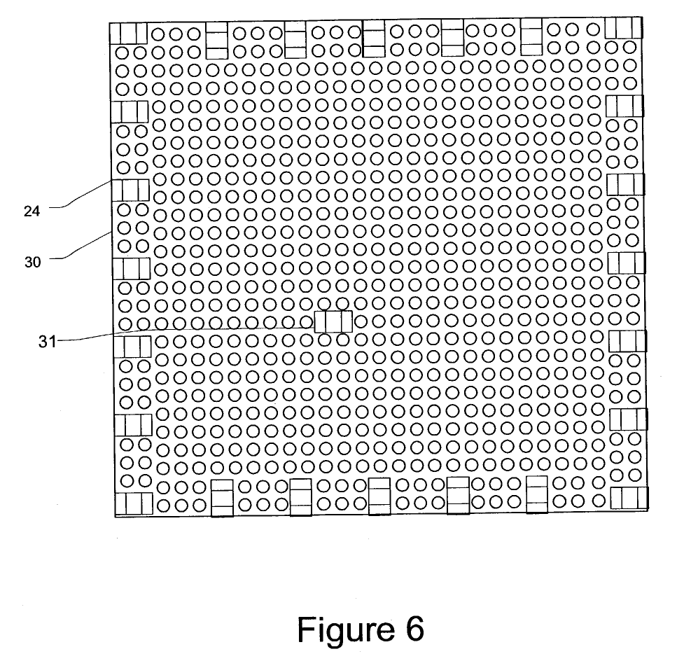

The capacitors should be mounted between the printed circuit board and the package. This can be accomplished by attaching the capacitors to the power and ground connections on the package, or by attaching them to the power and ground connections on the printed circuit board. FIG. 6 shows a diagram of what may be the bottom of the package 30 with the attached capacitors such as 24. Alternatively, the surface 30 may be the top surface of the printed circuit board where the package has not yet been mounted on it, but the capacitors have already been placed. The selection of where the capacitors are initially attached, either to the printed circuit board or the substrate, is left up to the process designer and may depend upon a particular process flow.

In addition to the other results of placing the capacitors between the substrate and the printed circuit board, this placement may aid in what is sometimes referred to as “dual referenced” board or substrate routing. High frequency operation of high frequency IO signals requires their routing with controlled characteristic impedance through the entire path between two integrated circuits connecting between them by means of two substrates and a board, such as a printed circuit board. To achieve that, the IO signals are routed in the substrate and the board either as a strip line or as micro-strip line. In case of a strip line the signal is routed in between two conductor planes called reference planes with the signal conductor isolated from the reference planes by a dielectric material. In the case of the micro-strip line, the signal line is separated by a dielectric material from a single reference plane.

Various permutations of substrate and board routing are possible. For example micro-strip line substrate routing may be combined with strip line board routing and then connect to the second substrate using a micro-strip line. All possible permutations of strip line and micro-strip line routing could exist between substrates and board routing. In addition to that, each of the reference planes may be either ground or power. In a simple case, the packages and board reference planes are ground, and a simple via galvanic connection is used to keep the continuity of the return path between the substrates and the board since the return paths in both the substrates and the board are of the same potential. However, layout constraints may lead to a situation where substrate signal referencing and board signal referencing are different.

For example, consider a case of micro-strip line substrate with signals referencing ground in the substrate combined with board signal routing in a micro-strip line configuration referencing the power plane. For return path continuity of the reference plane, in this example, it is impossible to short the substrate ground plane reference with the power plane reference of the board since both are at a different steady state voltage. In this case placing the capacitors in place of BGA balls provides a very effective method for keeping a high quality return path continuity for high frequency signals that change from either power or ground reference in the substrate routing to the opposite plane reference in the board.

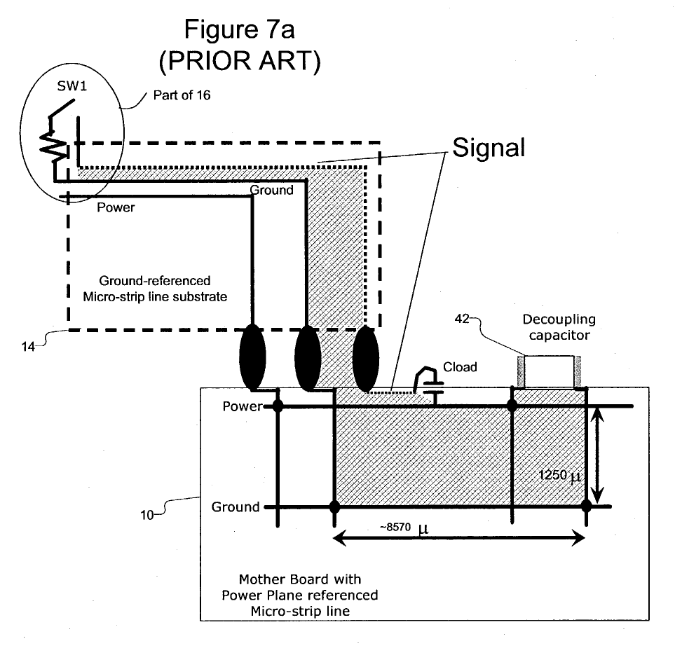

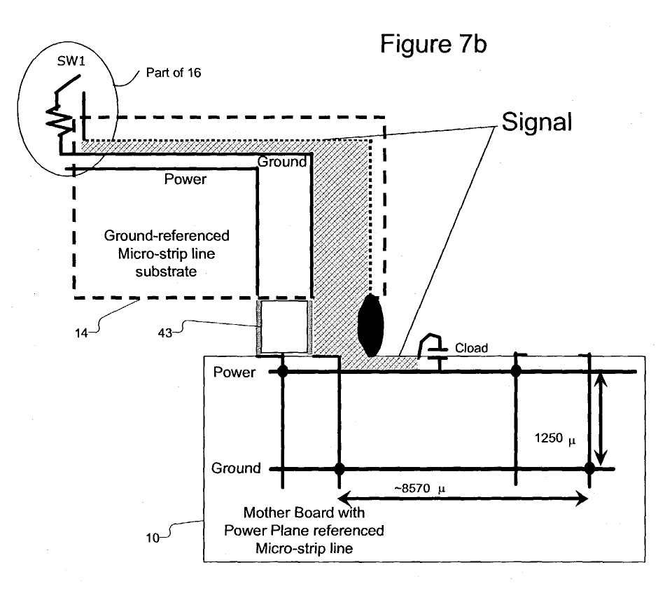

An example of such a prior art path is shown in FIG. 7a where the capacitor 42 is placed on the board outside the perimeter of the IC package. Initially the Cload capacitor symbolically representing the self-capacitor of the board transmission line was charged at both terminals to voltage level of the power rail. Activation of SW1 on the integrated circuit 16 will gradually discharge the terminal of Cload connected to the signal line until discharged to 0v ground potential. This will create a current flow shown by gray area in the transmission line of the board and the package. The completion of high frequency current flow path has to go through the terminals of the prior art capacitor 42 creating a large loop area of approximately 8570×1250μ². This adds a significant inductance to the return current flow path, which may significantly disrupt the uniform transmission line characteristic impedance on the transition between the substrate and the board resulting in significant signal quality degradation.

In an embodiment of the present invention, shown in FIG. 7b, a capacitor 43 is placed under the BGA substrate in order to create high frequency connection path between the substrate ground reference plane and board power plane. In this embodiment, the current flow path does not need to flow far away as it has the capacitor in the immediate vicinity of the ground BGA ball. Thus, the 8570×1250μ² current flow path loop area is eliminated resulting in much lower inductance of the return path transition between the substrate and the board. Mounting the capacitor between the substrate and printed circuit board can be extended for use anywhere around the package, including periphery I/O areas and central power delivery quadrants as shown at 31 in FIG. 6.

Although the examples shown in FIGS. 7a and 7b illustrate the case of ground referenced micro-strip line routing of substrate and power planed reference micro-strip line routine in the board, similar analysis and conclusions may be drawn for embodiments of the proposed invention for any other permutation of signal referencing for ground or power or both power and ground referencing, in case of strip line, and routing, either micro-strip or strip line.

The embodiments shown in the figures are generally directed towards periphery placement, but the capacitors placed as shown in embodiments of the invention can be beneficial for core power delivery.

Typically, the capacitors used in implementing embodiments of the invention will be standard multilayer ceramic chip capacitors (MLCC). In some instances, depending upon the substrate and the interconnect height, low-profile MLCC capacitors may be required.

Another possible issue with regard to MLCCs among other types of ceramic capacitors may be a possible coefficient of thermal expansion mismatch between the ceramic capacitor and the ball grid array interconnects, in which the capacitors may reside. One possible approach is to use an oversized stencil for the interconnects. Solder balls are typically deposited on the substrate using a stencil. Increasing the solder stencil size from 18 mil to 25 mil, for example, allows enough space to overcome any expansion issues caused by heat. Another approach may involve using oversized interconnects, where the interconnects have a greater vertical extent than current interconnects. This may be required due to the height of the capacitors used.

Throughout this discussion, focus has remained on capacitors as the SMT component that would benefit the most from embodiments of the invention. However, any SMT component, including resistors and inductors as examples, that have two or more terminals could be mounted using embodiments of the invention. No limitation to capacitors is intended by the use of capacitors as an illuminating example. Any SMT component could replace capacitors in the above discussions.

Thus, although there has been described to this point a particular embodiment for a method and apparatus for mounting capacitors in integrated circuit packaging and mounting to printed circuit boards, it is not intended that such specific references be considered as limitations upon the scope of this invention except in-so-far as set forth in the following claims.

What is claimed is:

1. An apparatus, comprising:
a board;
an integrated circuit package, mounted to the board; and
at least one surface mount component arranged between the board and the package.

2. The apparatus of claim 1, the component being mounted to the printed circuit board.

3. The apparatus of claim 1, the component being mounted to the package.

4. The apparatus of claim 1, the component being located so as to provide connection for power and ground from the substrate to the board.

5. The apparatus of claim 1, the component being selected from the group comprising: a capacitor, a resistor, an inductor, and a low-profile capacitor.

6. The apparatus of claim 1, the component being mounted as a ball grid array ball.

7. The apparatus of claim 1, the apparatus further comprising a heat sink in contact with the package.

8. A method of mounting capacitors, the method comprising:
providing a board;
mounting an integrated circuit package on the board; and
arranging at least one surface mount component between the package and the board.

9. The method of claim 8, wherein arranging the component further comprises attaching the component to the package prior to mounting the package on the board.

10. The method of claim 8, wherein arranging the component further comprises attaching the component to the board prior to mounting the package.

11. The method of claim 8, wherein arranging the component further comprises arranging the component so as to provide connection for power and ground from the package to the board.

12. An apparatus, comprising:
a board having power and ground paths;
an integrated circuit package mounted to the board such that power and ground paths of the package correspond to the power and ground paths on the board; and
at least one component arranged between the package and the board between one of the power paths and one of the ground paths.

13. The apparatus of claim 12, the component selected from the group comprising: a capacitor, an inductor, a resistor, and a low-profile capacitor.

14. The apparatus of claim 12, wherein the component is attached to the package.

15. The apparatus of claim 12, wherein the component is attached to the board.
